(19) United States
(12) Patent Application Publication
(10) Pub. No.: US 2024/0395501 A1
(43) Pub. Date: Nov. 28, 2024

(54) INDUCTIVELY COUPLED PLASMA PROCESSING APPARATUS

(71) Applicant: SAMSUNG ELECTRONICS CO., LTD., Suwon-si (KR)

(72) Inventors: Hyojin PARK, Suwon-si (KR); Songyun KANG, Suwon-si (KR); Jiyun JU, Suwon-si (KR)

(21) Appl. No.: 18/642,124

(22) Filed: Apr. 22, 2024

(30) Foreign Application Priority Data
May 24, 2023 (KR) 10-2023-0066794

(51) Int. Cl. H01J 37/32

(52) U.S. Cl. CPC H01J 37/32119; H01J 2237/327

(57) ABSTRACT

An inductively coupled plasma processing apparatus includes a main body having an internal space; a chamber in the internal space of the main body and having an open upper side and an open lower side; a window unit coupled to an upper portion of the chamber to form a processing space; and a coil in an upper portion of the window unit, wherein the coil is configured to form an electromagnetic field. The main body includes a substrate installation portion configured to receive a substrate so that the substrate is below the chamber. The window unit includes a plurality of windows, and each of the plurality of windows has a respective different thickness and/or a respective different material.

### CROSS-REFERENCE TO RELATED APPLICATION(S)

This application claims benefit of priority to Korean Patent Application No. 10-2023-0066794 filed on May 24, 2023, in the Korean Intellectual Property Office, the disclosure of which is incorporated herein by reference in its entirety.

### BACKGROUND

The present disclosure relates to an inductively coupled plasma processing apparatus.

An inductively coupled plasma processing apparatus is an apparatus configured to perform substrate processing such as a deposition process and an etching process, and a window is installed on a chamber body forming an enclosed processing space and a ceiling of the chamber body, and a radio frequency (RF) antenna is installed on an upper side of the window to apply power to the antenna, thus forming an induced electrical field in the processing space and performing substrate processing by converting a processing gas into plasma with the induced electrical field.

Controlling the distribution of an electromagnetic field in the inductively coupled plasma processing apparatus is an important factor directly related to process performance. Furthermore, in order to obtain the distribution of a desired electromagnetic field, improvements in the shape, structure and RF system of the antenna are generally implemented.

However, there may be a limit to controlling the distribution of the electromagnetic field by improving the shape, structure, and RF system of the antenna, and accordingly, it may be necessary to develop a structure to obtain the distribution of the desired electromagnetic field.

### SUMMARY

An aspect of the present disclosure is to provide an inductively coupled plasma processing apparatus configured to efficiently and accurately perform distribution control of an electromagnetic field.

According to an aspect of the present disclosure, an inductively coupled plasma processing apparatus may include: a main body having an internal space; a chamber in the internal space of the main body and having an open upper side and an open lower side; a window unit coupled to an upper portion of the chamber, wherein the window unit and the chamber form a processing space; and a coil in an upper portion of the window unit, wherein the coil is configured to form an electromagnetic field, wherein the main body may include a substrate installation portion configured to receive a substrate so that the substrate is below the chamber, the window unit may include a plurality of windows, and each of the plurality of windows may have a respective different thickness and/or different material.

According to the present disclosure, it is possible to provide an inductively coupled plasma processing apparatus configured to efficiently and precisely perform distribution control of an electromagnetic field.

Advantages and effects of the present application are not limited to the foregoing content and may be more easily understood in the process of describing a specific example embodiment of the present disclosure.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram of an inductively coupled plasma processing apparatus according to an example embodiment of the present disclosure;

FIG. 2 is a cross-sectional view illustrating a window unit provided in an inductively coupled plasma processing apparatus according to an example embodiment of the present disclosure;

FIG. 3 is a plan view illustrating a window unit provided in an inductively coupled plasma processing apparatus according to an example embodiment of the present disclosure;

FIG. 4 is a cross-sectional view illustrating a window unit provided in an inductively coupled plasma processing apparatus according to an example embodiment of the present disclosure;

FIG. 5 is a perspective view illustrating a window unit provided in an inductively coupled plasma processing apparatus according to an example embodiment of the present disclosure;

FIG. 6 is an explanatory view illustrating an electromagnetic field distribution formed by the window unit illustrated in FIG. 5;

FIG. 7 is a perspective view representing a window unit according to the related art;

FIG. 8 is an explanatory view illustrating an electromagnetic field distribution formed by a window unit according to the related art;

FIG. 9 is a plan view illustrating a window unit provided in an inductively coupled plasma processing apparatus according to an example embodiment of the present disclosure;

FIG. 10 is an explanatory view illustrating an electromagnetic field distribution formed by the window unit illustrated in FIG. 9;

FIG. 11 is a plan view illustrating a window unit provided in an inductively coupled plasma processing apparatus according to an example embodiment of the present disclosure;

FIG. 12 is an explanatory view illustrating an electromagnetic field distribution formed by the window unit illustrated in FIG. 11;

FIG. 13 is a plan view illustrating a window unit provided in an inductively coupled plasma processing apparatus according to an example embodiment of the present disclosure;

FIG. 14 is a plan view illustrating a window unit provided in an inductively coupled plasma processing apparatus according to an example embodiment of the present disclosure;

FIG. 15 is a plan view illustrating a window unit provided in an inductively coupled plasma processing apparatus according to an example embodiment of the present disclosure; and

FIG. 16 is a plan view illustrating a window unit provided in an inductively coupled plasma processing apparatus according to an example embodiment of the present disclosure.

### DETAILED DESCRIPTION

Hereinafter, example embodiments of the present disclosure will be described with reference to the accompanying drawings.

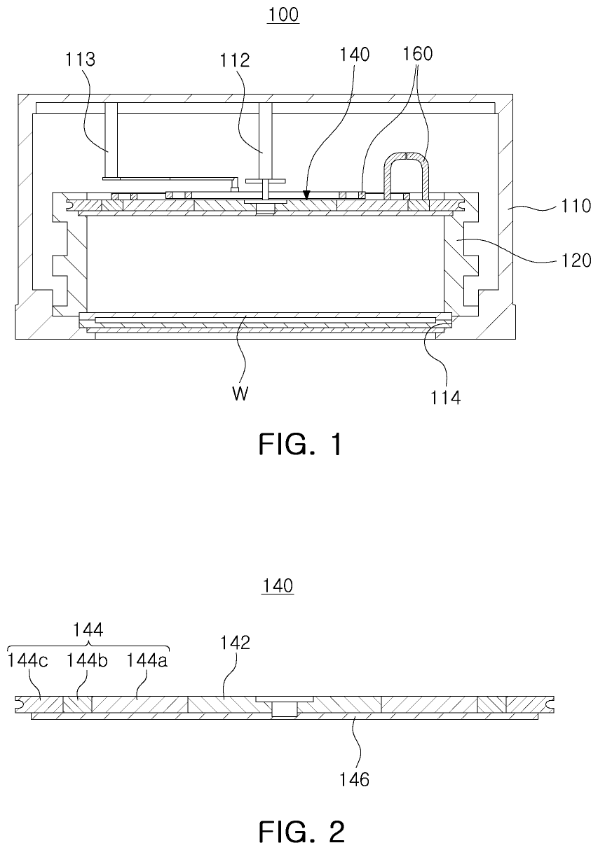

FIG. 1 is a schematic block diagram of an inductively coupled plasma processing apparatus according to an example embodiment of the present disclosure.

Referring to FIG. 1, an inductively coupled plasma processing apparatus 100 according to an example embodiment includes a main body 110, a chamber 120, a window unit 140 and a coil 160.

The main body 110 has an internal space. For example, the main body 110 may have a form in which a lower portion thereof is open. The main body 110 may be formed of, for example, a material including aluminum (Al). Furthermore, the main body 110 may be provided with a power supply portion 112 to supply power to the coil 160. Furthermore, the main body 110 may be provided with a ground portion 113 connected to the coil 160. The main body 110 may be provided with a substrate installation portion 114 in which a substrate W is installed so that the substrate W is disposed below the chamber 120. The substrate W may be seated on the substrate installation portion 114. For example, RF power may be applied or grounded in the substrate installation portion 114 depending on a process, and a heat transfer member (not illustrated) for cooling or heating may be installed in the substrate installation portion 114.

The chamber 120 is installed in the internal space of the main body 110 and may have a form in which an upper side and a lower side thereof are open. The chamber 120 may have, for example, a substantially hollow cylindrical shape. However, the present disclosure is not limited thereto, and the shape of the chamber 120 may have a shape corresponding to a shape of the substrate W. The chamber 120 forms a processing space S together with the window unit 140. For example, the chamber 120 may be connected to a vacuum pump (not illustrated) to control pressure in the processing space S and remove by-products. Furthermore, the chamber 120 may be provided with a gas injection unit (not illustrated) for supplying a process gas to the processing space S.

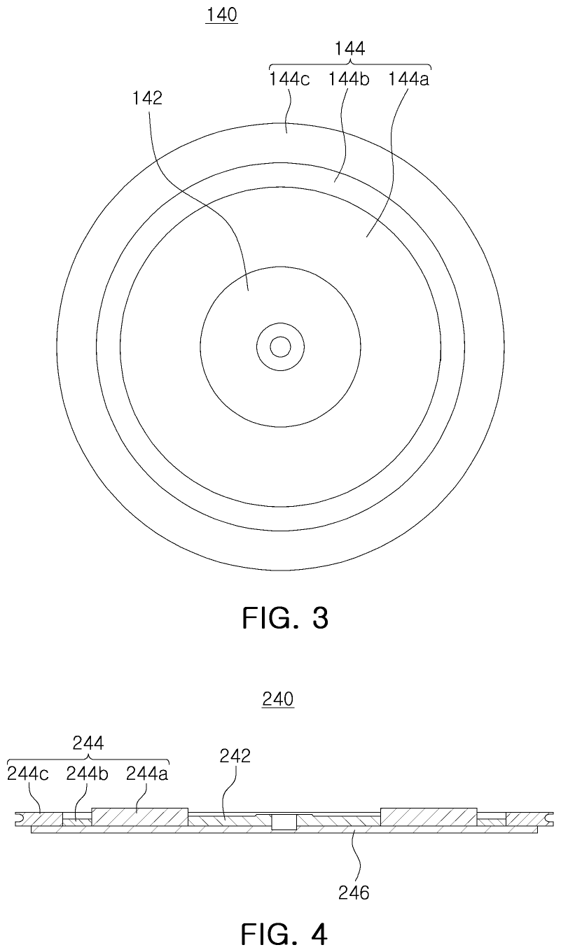

The window unit 140 is coupled to an upper portion of the chamber 120 to form the processing space S together with the chamber 120. For example, the window unit 140 may include a plurality of windows, and at least one of the plurality of windows may be formed of a different material. For example, the window unit 140 includes a first window 142, a second window 144, and a cover window 146, as described in more detail in FIGS. 2 and 3.

The first window 142 may be disposed in a central portion of the chamber 120 and may have a circular plate (i.e., flat disk) shape. The second window 144 may be disposed outside (i.e., concentrically surrounds) the first window 142 and may have a circular ring shape. For example, the second window 144 may have a second-first window 144a that concentrically surrounds the first window 142, a second-second window 144b that concentrically surrounds the second-first window 144a, and a second-third window 144c that concentrically surrounds the second-second window 144b, as illustrated. For example, at least one of the second-first window 144a to the second-third window 144c may be formed of different materials. Furthermore, as an example, the first window 142 and the second window 144 may also be formed of different materials. The cover window 146 may have a circular plate (i.e., flat disk) shape, and the first window 142 and the second window 144 may be disposed on an upper surface of the cover window 146. Furthermore, at least one of the cover window 146, the first window 142, and the second window 144 may be formed of a different material. The first window 142, the second window 144, and the cover window 146, constituting the window unit 140, may be formed of a material including one of quartz, ceramic (Al₂O₃), stainless (SUS), a permalloy, and aluminum (Al).

In this manner, distribution control of the electromagnetic field may be efficiently and precisely performed through the first window 142 and the second window 144 formed of different materials.

The coil 160 is disposed in an upper portion of the window unit 140 to form an electromagnetic field. For example, the coil 160 may have a substantially circular spiral shape to correspond to a shape of the window 140 and may be disposed in a circular region to form an induced electrical field in the processing space S, and may have various shapes depending on a size of a substrate W to be processed and a processing process condition.

As described above, the window unit 140 may include the first window 142, the second window 144, and the cover window 146, and at least one of the first window 142, the second window 144 and the cover window 146 and/or at least one of the second-first window 144a to the second-third window 144c may be formed of different materials, thereby efficiently and accurately controlling the distribution of an electromagnetic field.

FIG. 4 is a cross-sectional view illustrating a window unit provided in an inductively coupled plasma processing apparatus according to an example embodiment of the present disclosure.

Referring to FIG. 4, a window unit 240 includes a first window 242, a second window 244, and a cover window 246.

The first window 242 may be disposed in a central portion of the chamber 120 (see FIG. 1) and may have a circular plate (i.e., disk) shape. The second window 244 may concentrically surround the first window 242 and may have a circular ring shape. For example, the second window 244 may have a second-first window 244a that concentrically surrounds the first window 242, a second-second window 244b that concentrically surrounds the second-first window 244a, and a second-third window 244c that concentrically surrounds the second-second window 244b, as illustrated. For example, at least one of the second-first window 244a to the second-third window 244c may have different thicknesses. Furthermore, as an example, the first window 242, and the second-first window 244a to the second-third window 244c of the second window 244 may also have different thicknesses. The cover window 246 has a circular plate (i.e., flat disk) shape, and the first window 242 and the second window 244 may be disposed on an upper surface of the cover window 246. Furthermore, the cover window 246 may have a different thickness from those of the first window 242 and the second window 244. The first window 242, the second window 244, and the cover window 246, constituting the window unit 240, may be formed of one of quartz, ceramic (Al₂O₃), stainless steel (SUS), a permalloy, and aluminum (Al).

In this manner, the distribution control of the electromagnetic field may be efficiently and precisely performed through the first window 242 and the second window 244 having different thicknesses.

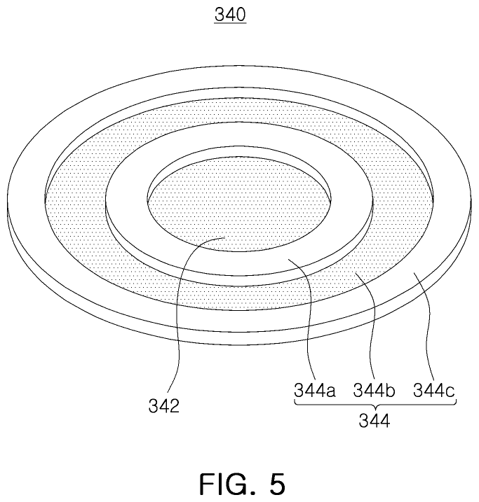

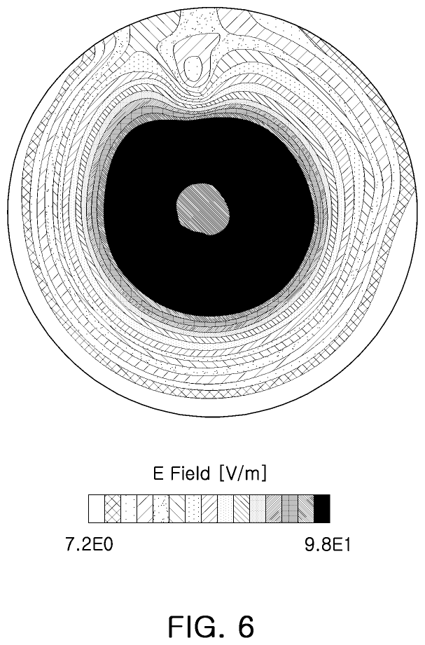

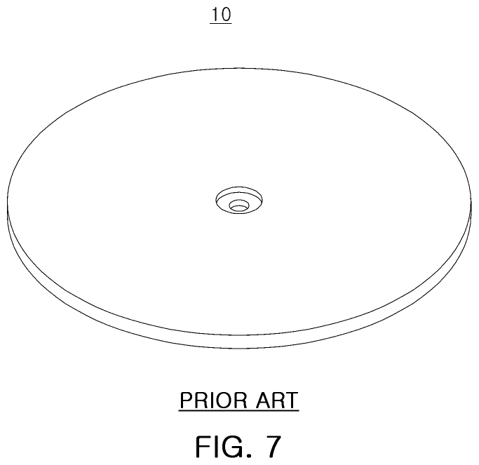

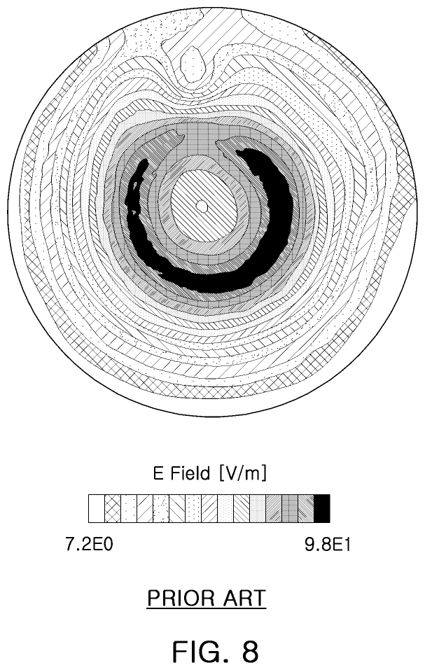

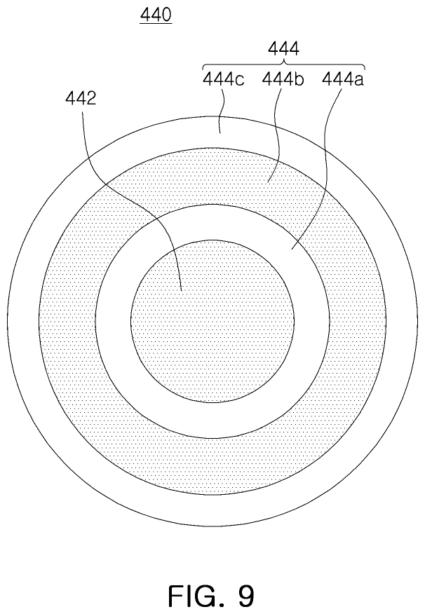

FIG. 5 is a perspective view illustrating a window unit provided in an inductively coupled plasma processing apparatus according to an example embodiment of the present disclosure, FIG. 6 is an explanatory view illustrating an electromagnetic field distribution formed by the window unit illustrated in FIG. 5, FIG. 7 is a perspective view representing a window unit according to the related art, and FIG. 8 is an explanatory view illustrating an electromagnetic field distribution formed by a window unit according to the related art.

Referring to FIG. 5, a window unit 340 may have a circular plate (i.e., disk) shape. The window unit 340 may include a first window 342 and a second window 344. The first window 342 may have, for example, a circular plate (i.e., flat disk) shape. The second window 344 concentrically surrounds the first window 342 and may have a circular ring shape. For example, the second window 344 may have a second-first window 344a that concentrically surrounds the first window 342, a second-second window 344b that concentrically surrounds the second-first window 344a, and a second-third window 344c that concentrically surrounds the second-second window 344b, as illustrated. For example, the first window 342 and the second-second window 344b may have the same thickness, and the second-first window 344a and the second-third window 344c may have the same thickness. The second-first window 344a and the second-third window 344c may have a thickness greater than that of the first window 342 and the second-second window 344b.

Referring to FIG. 7, the window unit 10 according to the related art has a circular plate (i.e., flat disk) shape having the same (i.e., uniform) thickness.

Furthermore, it may be seen that the second-first window 344a and the second-third window 344c represent the electromagnetic field distribution as illustrated in FIG. 6 when they are thicker than the first window 342 and the second-second window 344b. Furthermore, as illustrated in FIG. 6, it may be seen that, as compared to an electromagnetic field distribution formed by a window unit according to the related art shown in FIG. 8, an intensity of a central portion of an electromagnetic field becomes stronger. Accordingly, it may be seen that the weakening of the electromagnetic field in the central portion may be improved.

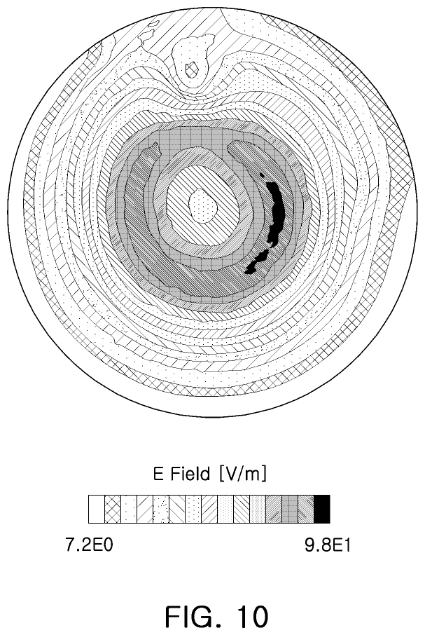

FIG. 9 is a plan view illustrating a window unit provided in an inductively coupled plasma processing apparatus according to an example embodiment of the present disclosure, and FIG. 10 is an explanatory view illustrating an electromagnetic field distribution formed by the window unit illustrated in FIG. 9

Referring to FIG. 9, a window unit 440 may have a circular plate (i.e., disk) shape. The window unit 440 may include a first window 442 and a second window 444. The first window 442 may have, for example, a circular plate (i.e., flat disk) shape. The second window 444 concentrically surrounds the first window 442 and may have a circular ring shape. For example, the second window 444 may have a second-first window 444a that concentrically surrounds the first window 442, a second-second window 444b that concentrically surrounds the second-first window 444a, and a second-third window 444c that concentrically surrounds the second-second window 444b, as illustrated. For example, the first window 442 and the second-second window 444b may be formed of the same material. For example, the first window 442 and the second window 444b may be formed of a quartz material. Furthermore, as an example, the second-first window 444a and the second-third window 444c may be formed of the same material. For example, the second-first window 444a and the second-third window 444c may be formed of a ceramic (Al₂O₃) material.

As described above, it may be seen that the second-first window 444a and the second-third window 444c may be formed of different materials from those of the first window 442 and the second-second window 444b, thus representing the distribution of an electromagnetic field as illustrated in FIG. 10. Furthermore, as described in FIG. 10, it may be seen that, as compared to the electromagnetic field distribution formed by the window unit according to the related art illustrated in FIG. 8, an intensity of an electromagnetic field is reduced in a region in which the second-first window 444a and the second-third window 444c are disposed.

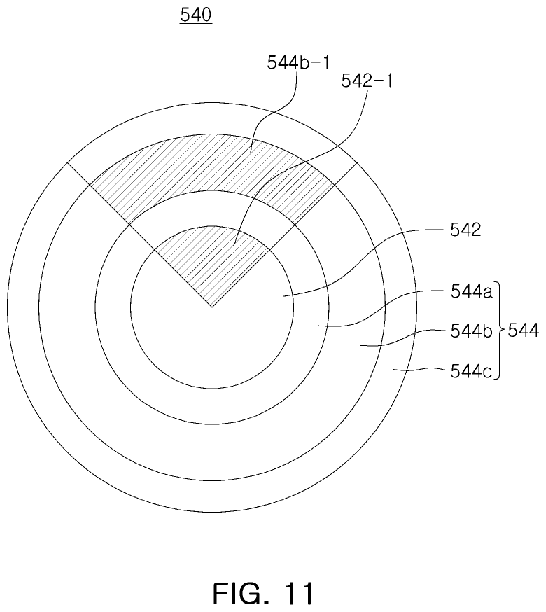

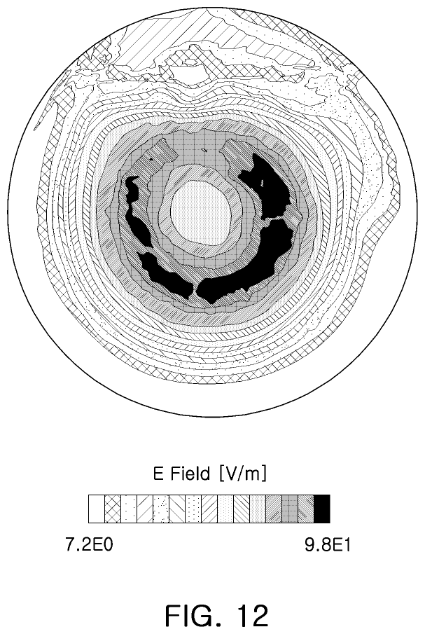

FIG. 11 is a plan view illustrating a window unit provided in an inductively coupled plasma processing apparatus according to an example embodiment of the present disclosure, and FIG. 12 is an explanatory view illustrating an electromagnetic field distribution formed by the window unit illustrated in FIG. 11

Referring to FIG. 11, a window unit 540 may have a circular plate (i.e., disk) shape. The window unit 540 may include a first window 542 and a second window 544 that concentrically surrounds the first window 542. The first window 542 may have, for example, a circular plate (i.e., flat disk) shape. The second window 544 concentrically surrounds the first window 542 and may have a circular ring shape. For example, the second window 544 may have a second-first window 544a that concentrically surrounds the first window 542, a second-second window 544b that concentrically surrounds the second-first window 544a, and a second-third window 544c that concentrically surrounds the second-second window 544b, as illustrated. For example, the first window 542 may include a first region 542-1 having a material different from that of other portions of the first window 542. The first region 542-1 may be formed of a ceramic (Al₂O₃) material, and the remaining first window 542 except for the first region 542-1 may be formed of a quartz material. The second-second window 544b may include a second region 544b-1 having a material different from that of other portions of the second-second window 544b. The second region 544b-1 may be formed of a ceramic (Al₂O₃) material, and the remaining second-second window 544b except for the second region 544b-1 may be formed of a quartz material. The second-first window 544a and the second-third window 544c may be formed of a quartz material.

As described above, the first window 542 includes the first region 542-1 having a material different from that of other portions, and the second-second window 544b includes the second region 544b-1 having a material different from that of other portions. Accordingly, as illustrated in FIG. 12, it may be seen that, as compared to the electromagnetic field distribution formed by the window unit according to the related art illustrated in FIG. 8, an intensity of the electromagnetic field is reduced in a region in which the first region 542-1 and the second region 544b-1 are disposed.

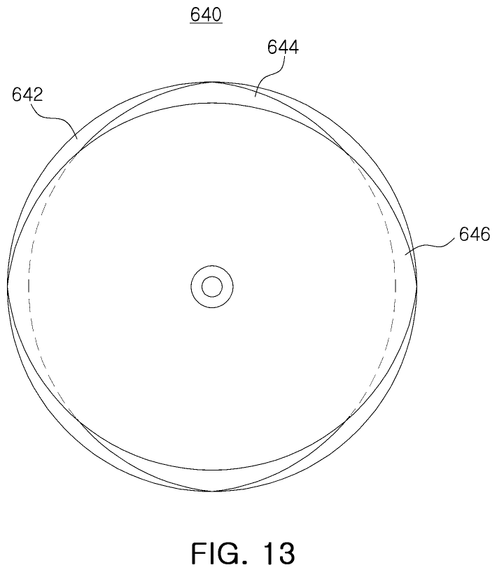

FIG. 13 is a plan view illustrating a window unit provided in an inductively coupled plasma processing apparatus according to an example embodiment of the present disclosure.

Referring to FIG. 13, a window unit 640 may include a first window 642, a second window 644, and a third window 646. For example, the first window 642, the second window 644, and the third window 646 may be sequentially stacked. The first window 642 may have, for example, a circular plate (i.e., disk) shape. Furthermore, the second window 644 and the third window 646 are disposed inside (i.e., are within the outer diameter of) the first window 644, as illustrated. Furthermore, as an example, the second window 644 and the third window 646 have the same shape, and the third window 646 may be distorted at an angle of approximately 90° based on the second window 644. The first window 642 may be formed of a material different from that of the second window 644 and the third window 646. As an example, any one of the second window 644 and the third window 646 may be formed of a metal material. The first window 642 may be formed of, for example, a quartz material.

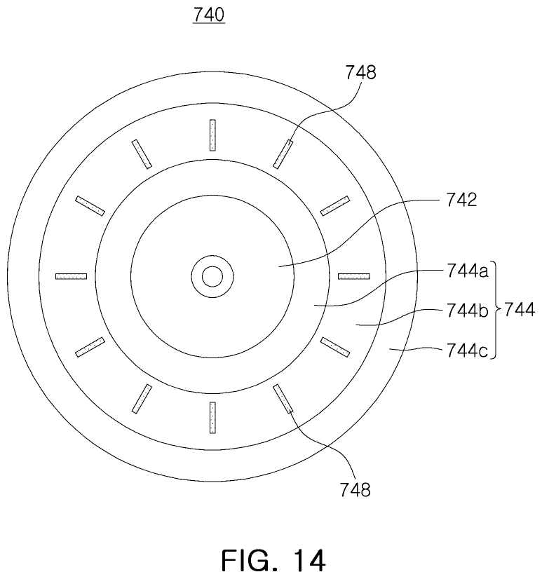

FIG. 14 is a plan view illustrating a window unit provided in an inductively coupled plasma processing apparatus according to an example embodiment of the present disclosure.

Referring to FIG. 14, a window unit 740 may have a circular plate (i.e., disk) shape. The window unit 740 may include a first window 742 and a second window 744 that concentrically surrounds the first window 742. The first window 742 may have, for example, a circular plate (i.e., flat disk) shape. The second window 744 concentrically surrounds the first window 742 and may have a circular ring shape. For example, the second window 744 may have a second-first window 744a that concentrically surrounds the first window 742, a second-second window 744b that concentrically surrounds the second-first window 744a, and a second-third window 744c that concentrically surrounds the second-second window 744b, as illustrated. The second-second window 744b may include an insertion layer 748 having a slit shape, as illustrated. The insertion layer 748 is disposed to face the center of the window unit 740, and a plurality of insertion layers 748 may be spaced apart from each other in a circumferential direction, as illustrated. The insertion layer 748 may be formed of a material different from that of the second-second window 744b.

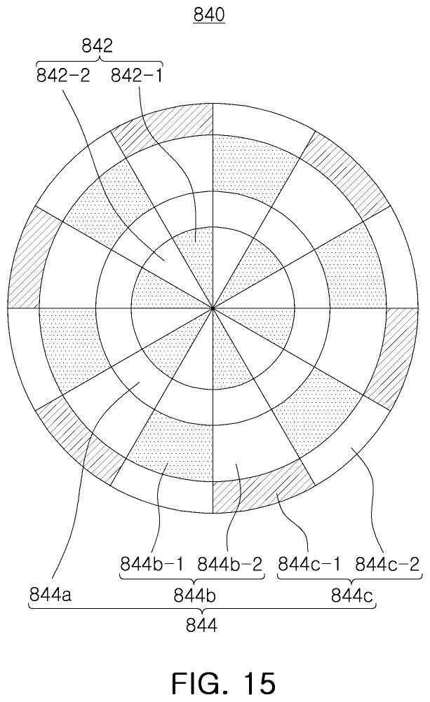

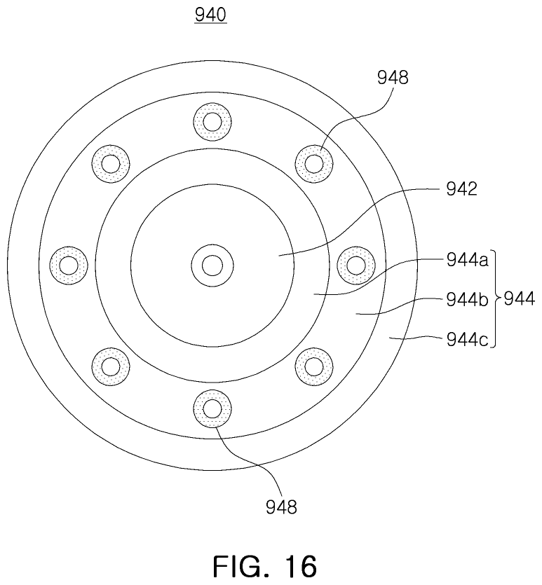

FIG. 15 is a plan view illustrating a window unit provided in an inductively coupled plasma processing apparatus according to an example embodiment of the present disclosure.

Referring to FIG. 15, a window unit 840 may have a circular plate (i.e., disk) shape. The window unit 840 may include a first window 842 and a second window 844. The first window 842 may have, for example, a circular plate (i.e., disk) shape. The second window 844 concentrically surround the first window 842 and may have a circular ring shape. For example, the second window 844 may have a second-first window 844a that concentrically surrounds the first window 842, a second-second window 844b that concentrically surrounds the second-first window 844a, and a second-third window 844c that concentrically surrounds the second-second window 844b. The first window 842 may include a first region 842-1 having an arc shape and a second region 842-2 alternately arranged with the first region 842-1 in the circumferential direction, as illustrated. The first region 842-1 and the second region 842-2 may be formed of different materials. The second-second window 844b may include a third region 844b-1 having an arc shape and a fourth region 844b-2 alternately arranged with the third region 844b-1 in the circumferential direction, as illustrated. The third region 844b-1 and the fourth region 844b-2 may be formed of different materials. Furthermore, the second-third window 844c may include a fifth region 844c-1 having a band shape and a sixth region 844c-2 alternately arranged with the fifth region 844c-1 in the circumferential direction. The fifth region 844c-1 and the sixth region 844c-2 may be formed of different materials.

FIG. 16 is a plan view illustrating a window unit provided in an inductively coupled plasma processing apparatus according to an example embodiment of the present disclosure.

Referring to FIG. 16, a window unit 940 may have a circular plate (i.e., disk) shape. The window unit 940 may include a first window 942 and a second window 944 that concentrically surrounds the first window 942. The first window 942 may have, for example, a circular plate (i.e., flat disk) shape. The second window 944 that concentrically surrounds the first window 942 may have a circular ring shape. For example, the second window 944 may include a second-first window 944a that concentrically surrounds the first window 942, a second-second window 944b that concentrically surrounds the second-first window 944a, and a second-third window 944c that concentrically surrounds the second-second window 944b. The second-second window 944b may include an insertion layer 948 having a circular ring shape. A plurality of insertion layers 948 may be spaced apart from each other in the circumferential direction, as illustrated. The insertion layer 948 may be formed of a material different from that of the second-second window 944b.

Although the example embodiment of the present disclosure has been described in detail above, it will be obvious to those skilled in the art that the scope of the present disclosure is not limited thereto, and various modifications and variation may be made without departing from the technical concept of the present disclosure described in the claims.

What is claimed is:

1. An inductively coupled plasma processing apparatus comprising:
a main body having an internal space;
a chamber in the internal space of the main body and comprising an open upper side and an open lower side;
a window unit coupled to an upper portion of the chamber, wherein the window unit and the chamber form a processing space; and
a coil in an upper portion of the window unit, wherein the coil is configured to form an electromagnetic field,
wherein the main body comprises a substrate installation portion configured to receive a substrate so that the substrate is below the chamber,
wherein the window unit comprises a plurality of windows, and
wherein each of the plurality of windows comprises a respective different thickness and/or different material.

2. The inductively coupled plasma processing apparatus of claim 1, wherein the window unit comprises a plurality of concentric windows.

3. The inductively coupled plasma processing apparatus of claim 2, wherein the plurality of concentric windows comprise a first window having a flat disk shape, and at least one second window having a ring shape, wherein the at least one second window concentrically surrounds the first window.

4. The inductively coupled plasma processing apparatus of claim 3, further comprising a cover window, and wherein the first window and the at least one second window are on an upper surface of the cover window.

5. The inductively coupled plasma processing apparatus of claim 4, wherein the at least one second window comprises a plurality of second windows, and wherein each of the plurality of second windows comprises a respective different material.

6. The inductively coupled plasma processing apparatus of claim 5, wherein the first window and the at least one second window each comprise a different material.

7. The inductively coupled plasma processing apparatus of claim 6, wherein the first window, the at least one second window, and the cover window each comprise a respective different material.

8. The inductively coupled plasma processing apparatus of claim 3, wherein the at least one second window comprises a plurality of second windows, and wherein at least one of the plurality of second windows has a thickness that is different from a thickness of other ones of the plurality of second windows.

9. The inductively coupled plasma processing apparatus of claim 8, wherein a thickness of the first window is different from a thickness of the at least one second window.

10. The inductively coupled plasma processing apparatus of claim 9, further comprising a cover window, and wherein the first window and the at least one second window are on an upper surface of the cover window.

11. The inductively coupled plasma processing apparatus of claim 1, wherein
one of the plurality of windows comprises an insertion layer having a slit or circular ring shape.

12. The inductively coupled plasma processing apparatus of claim 1, wherein the window unit comprises one of quartz, ceramic (Al₂O₃), stainless steel (SUS), a permalloy, and aluminum (Al).

13. The inductively coupled plasma processing apparatus of claim 1, wherein the plurality of windows overlap each other.

14. The inductively coupled plasma processing apparatus of claim 1, wherein each of the plurality of windows has a respective different size and/or shape.

15. An inductively coupled plasma processing apparatus comprising:
a main body having an internal space;
a chamber in the internal space of the main body and comprising an open upper side and an open lower side;
a window unit coupled to an upper portion of the chamber; and
a coil in an upper portion of the window unit, wherein the coil is configured to form an electromagnetic field,
wherein the window unit comprises a plurality of windows, and
wherein the plurality of windows overlap each other, and at least one of the plurality of windows comprises a metal material.

16. The inductively coupled plasma processing apparatus of claim 15, wherein at least one of the plurality of windows has a shape that is different from other ones of the plurality of windows.

17. An inductively coupled plasma processing apparatus comprising:
a main body having an internal space;
a chamber in the internal space of the main body; and
a window unit coupled to an upper portion of the chamber, wherein the window unit and the chamber form a processing space;
wherein the window unit comprises a first window having a flat disk shape, and at least one second window that concentrically surrounds the first window.

18. The inductively coupled plasma processing apparatus of claim 17, wherein the first window and the at least one second window each comprise a respective different thickness and/or different material.

19. The inductively coupled plasma processing apparatus of claim 17, further comprising a cover window, and wherein the first window and the at least one second window are on an upper surface of the cover window.

20. The inductively coupled plasma processing apparatus of claim 4, wherein the at least one second window comprises a plurality of second windows, and wherein at least one of the plurality of second windows has a thickness that is different from a thickness of other ones of the plurality of second windows.
